(19) United States
(12) Patent Application Publication
(10) Pub. No.: US 2018/0326715 A1
(43) Pub. Date: Nov. 15, 2018

(54) PRINTING DEVICE AND PRINTING METHOD BASED ON DIGITAL PRINTING

(71) Applicant: Shenzhen Textalk Graphic Technology Co., Ltd., Shenzhen City (CN)

(72) Inventors: Shoubin Wang, Shenzhen City (CN); Wenhong Wang, Shenzhen City (CN)

(21) Appl. No.: 15/590,670

(22) Filed: May 9, 2017

(51) Int. Cl. B41F 1/38; G03F 7/00; B41J 3/54; B41F 1/18

(52) U.S. Cl. CPC B41F 1/38; G03F 7/0035; B41F 1/26; B41F 1/18; B41J 3/546

(57) ABSTRACT

A printing device based on digital printing and a printing method based on digital printing are disclosed, wherein the printing device comprises a rack and a platen, wherein the rack is provided with a plurality of functional zones, the functional zones comprise a feeding zone, an underpainting printing zone, a pattern printing zone and an unloading zone; the platen is used for placing a medium to be printed, and is transferred among the feeding zone, the underpainting printing zone, the pattern printing zone and the unloading zone to achieve a continuous printing process. Therefore, only a digital printing device is needed to complete the underpainting and pattern printing, without incorporating a silk net printing machine and an ink jet printing machine, which is advantageously saving the enterprise cost, omitting a step of materials transferring among different equipment, and improving the production efficiency.

### TECHNICAL FIELD

The present disclosure relates to the field of printing, and more particularly, to a printing device, and a printing method.

### BACKGROUND

In the printing and dyeing industry, darker media need to be sprayed and printed with a layer of light-colored underpainting in advance, and then the underpainting is sprayed and printed with patterns, so that it's possible to avoid the color of the media from covering the patterns. In the prior art, the medium is firstly placed on a silk net printing machine for printing with underpainting, then it is placed on an ink jet printing machine for spraying and printing the pattern. However, the silk net printing machine and the ink jet printing machine need to be purchased in this case, which greatly increases the enterprise cost; and according to different technologies, the medium needs to be transferred among different equipment, which limits the improvement of the production efficiency.

### SUMMARY

In order to overcome the deficiencies in the prior art, the present disclosure provides a printing device based on digital printing.

The present disclosure further provides a printing method.

In order to solve the above technical problems, the disclosure employs technical solutions as follows:

A printing device based on digital printing comprises a rack and a platen, wherein the rack is sequentially provided with a plurality of functional zones, the functional zones comprise a feeding zone, an underpainting printing zone, a pattern printing zone and an unloading zone. the platen is used for placing a medium to be printed, and is transferred among the feeding zone, the underpainting printing zone, the pattern printing zone and the unloading zone to achieve a continuous printing process.

As a further improvement of the foregoing solution, the functional zones further comprise a pre-treating fluid spraying zone arranged between the feeding zone and the underpainting printing zone.

As a further improvement of the foregoing solution, the functional zones further comprise a drying zone arranged between the pre-treating fluid spraying zone and the underpainting printing zone, and/or between the underpainting printing zone and the pattern printing zone.

As a further improvement of the foregoing solution, the functional zones further comprise a glue spraying zone arranged between the pattern printing zone and the unloading zone.

As a further improvement of the foregoing solution, the functional zones further comprise a flocking zone and/or a gold blocking zone arranged between the glue spraying zone and the unloading zone.

As a further improvement of the foregoing solution, the functional zones further comprise a drying zone arranged between the pattern printing zone and the glue spraying zone.

As a further improvement of the foregoing solution, the feeding zone, the underpainting printing zone, the pattern printing zone and the unloading zone are annularly distributed.

As a further improvement of the foregoing solution, the quantity of the platen is not less than that of the functional zones, so that a platen in the unloading zone accesses into the feeding zone after a platen in the feeding zone accesses into a next functional zone.

A printing method based on digital printing, comprising the following steps of:

S10: preparing a printing device, the printing device comprising a rack and a platen, the rack being provided with a feeding zone, an underpainting printing zone, a pattern printing zone and an unloading zone;
S20: fixing a medium to be printed on the platen in the feeding zone;
S30: moving the platen to the underpainting printing zone, printing underpainting in the underpainting printing zone by digital printing;
S40 moving the platen to the pattern printing zone after completing underpainting printing, and printing a pattern in the pattern printing zone by digital printing; and
S50 moving the platen to the unloading zone after completing pattern printing, and implementing unloading operation in the unloading zone.

As a further improvement of the foregoing solution, the printing method further comprises a step of spraying pre-treating fluid before the step of printing underpainting.

As a further improvement of the foregoing solution, the printing method further comprises a step of drying before the step of printing pattern and after completing the step of spraying the pre-treating fluid.

As a further improvement of the foregoing solution, the printing method further comprises a step of spraying glue before the step of unloading and after the step of printing pattern.

As a further improvement of the foregoing solution, the printing method further comprises one of or combination of a step of flocking, a step of gold blocking and a step of drying before the step of unloading and after completing the step of spraying glue.

The present disclosure has the advantageous effects that:

A digital printing device according to the present disclosure can be used to complete the underpainting and pattern printing, without incorporating a silk net printing machine and an ink jet printing machine, which is advantageously saving the enterprise cost, omitting a step of materials transferring among different equipment, and improving the production efficiency.

### BRIEF DESCRIPTION OF THE DRAWINGS

The present disclosure will be further described in details hereunder with reference to the drawings and the embodiments, in which:

FIG. 1 is a system configuration schematic diagram of the first embodiment of the present disclosure.

FIG. 2 is a system configuration schematic diagram of the second embodiment of the present disclosure.

FIG. 3 is a system configuration schematic diagram of the third embodiment of the present disclosure.

FIG. 4 is a system configuration schematic diagram of the fourth embodiment of the present disclosure.

FIG. 5 is a system configuration schematic diagram of the fifth embodiment of the present disclosure.

### DETAILED DESCRIPTION OF THE EMBODIMENTS

The conception, specific structure and resulting technical effect of the disclosure will be described clearly and fully with reference to the embodiments and the drawings hereunder, so as to fully understand the object, technical solution and effect of the disclosure. It should be noted that the embodiments in the application and the features in the embodiment can be mutually combined under in non-conflict conditions.

It should be noted that unless otherwise specified herein, when a certain feature is referred to as to “fixed” or “connected” to the other feature, it is not only directly fixed or connected to the other feature, but also it can be indirectly fixed or connected to the other feature. In addition, the descriptions like “up”, “down”, “left” and “right” used in the disclosure are merely relative to the mutual position relation of various components of the disclosure in the drawings.

In addition, unless otherwise defined, the meanings of all technologies and scientific terms used herein are the same as those generally understood by those skilled in the art. The terms used herein are merely for describing the specific embodiment, but not intended to limit the disclosure. The terms “and/or” used herein include any combinations of one or more related listed items.

The present description and claims may make use of the terms “a,” “at least one of,” and “one or more of” with regard to particular features and elements of the illustrative embodiments. It should be appreciated that these terms and phrases are intended to state that there is at least one of the particular feature or element present in the particular illustrative embodiment, but that more than one can also be present. That is, these terms/phrases are not intended to limit the description or claims to a single feature/element being present or require that a plurality of such features/elements be present. To the contrary, these terms/phrases only require at least a single feature/element with the possibility of a plurality of such features/elements being within the scope of the description and claims.

In addition, it should be appreciated that the following description uses a plurality of various examples for various elements of the illustrative embodiments to further illustrate example implementations of the illustrative embodiments and to aid in the understanding of the mechanisms of the illustrative embodiments. These examples intended to be non-limiting and are not exhaustive of the various possibilities for implementing the mechanisms of the illustrative embodiments. It will be apparent to those of ordinary skill in the art in view of the present description that there are many other alternative implementations for these various elements that may be utilized in addition to, or in replacement of, the examples provided herein without departing from the spirit and scope of the present disclosure.

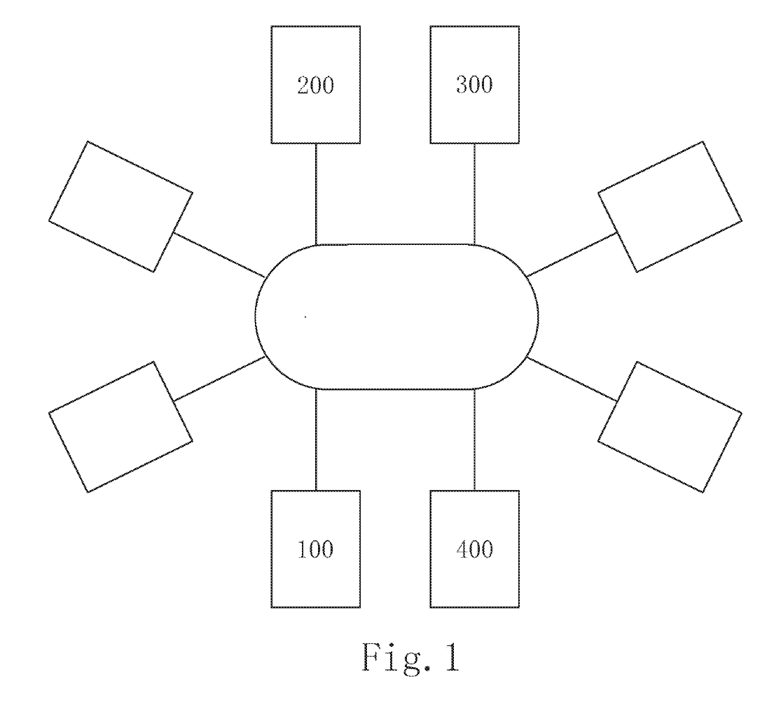

FIG. 1 shows a system configuration schematic diagram of the first embodiment of the present disclosure. As shown in the drawing, the present disclosure comprises a rack and a platen (not shown), the rack is provided with a plurality of functional zones, the functional zones comprise but not limited to a feeding zone 100 for medium to be printed, an underpainting printing zone 200, a pattern printing zone 300 and an unloading zone 400 for printed medium as shown in FIG. 1. The rack is provided with an underpainting digital printing device and a pattern digital printing device in positions corresponding to the underpainting printing zone 200 and the pattern printing zone 300 respectively, wherein both the underpainting digital printing device and the pattern digital printing device can be either two printing modules in an integrated printing component or two separate printing devices; in addition, all the rack, the underpainting digital printing device, the pattern digital printing device and a device for driving the platen to move can adopt those in the prior art, which are not specifically limited in the present disclosure.

The platen is used for fixing the medium to be printed. The medium is commonly a ready-to-wear or a cutting piece. Before printing, a binding element is coated manually or by a mechanism on a supporting plane of the platen, and then the medium is evenly placed on a binding surface. After the medium is fixed, the platen is moved to the underpainting printing zone 200 from the feeding zone 100, the underpainting is printed on the medium through the underpainting digital printing device; the platen is moved to the pattern printing zone 300 after completing the underpainting printing, patterns are printed on the underpainting through the pattern digital printing device; the platen is moved to the unloading zone 400 for unloading operation after printing the patterns; and then the platen is returns to the feeding zone 100 to wait for next feeding. Only a digital printing device is needed according to the present disclosure to complete the underpainting and pattern printing, without incorporating a silk net printing machine and an ink jet printing machine, which is advantageously saving the enterprise cost, omitting a step of materials transferring among different equipment, and improving the production efficiency.

Preferably, the feeding zone 100, the underpainting printing zone 200, the pattern printing zone 300 and the unloading zone 400 are annularly distributed, in particular, elliptically distributed, such that the space occupation of the equipment can be reduced.

Preferably, the embodiment comprises at least four platens, namely, each functional zone corresponds to at least one platen. After the platen in the feeding zone 100 is loaded with the medium and accesses into the underpainting printing zone 200, the platen in the unloading zone 400 can access into the feeding zone 100 for feeding operation in time, thus a continuous printing process is achieved, which further improves the production efficiency.

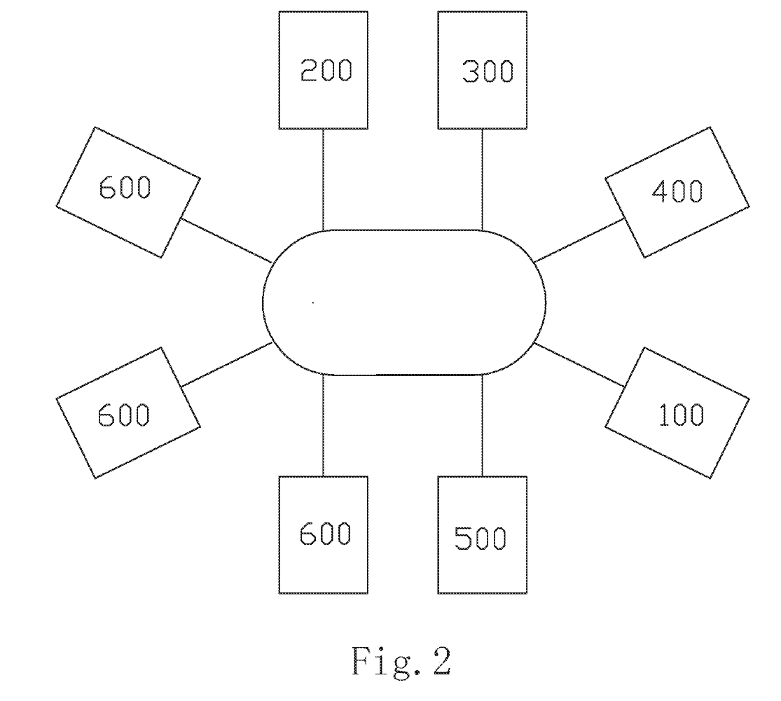

FIG. 2 shows a three-dimensional schematic diagram of the second embodiment of the present disclosure. As shown in the drawing, the different between the second embodiment and the first embodiment lies in that, a pre-treating fluid spraying zone 500 is further arranged between the feeding zone 100 and the underpainting printing zone 200, the embodiment is applicable to those medium which need to be sprayed pre-treating fluid before printing. Further, a drying zone 600 is further arranged between the pre-treating fluid spraying zone 500 and the underpainting printing zone 200, for drying the medium sprayed with the pre-treating fluid. For different medium, drying degrees are also different. In the present disclosure, the drying degree is controlled by the quantity of the drying zones 600. Three drying zones 600 are provided along a heading direction of the medium as shown in the drawing. The pre-treating spraying zone 500 and the drying zone 600 is respectively provided with a pre-treating spraying device and a drying device, which can be selected from those in the prior art, and which are not specifically limited in the present disclosure.

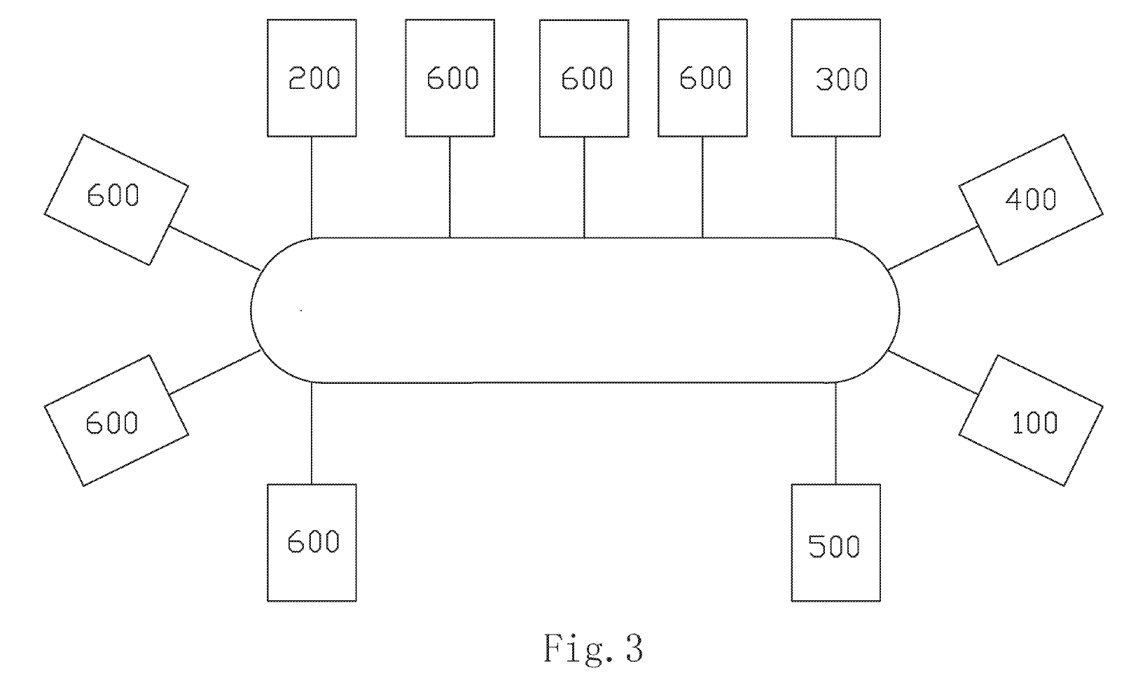

FIG. 3 shows a three-dimensional schematic diagram of the third embodiment of the present disclosure. As shown in the drawing, the difference between the third embodiment and the second embodiment lies in that, the drying zone 600 is also arranged between the underpainting printing zone 200 and the pattern printing zone 300, and the quantity of the drying zones 600 can also be regulated according to the drying degree in a similar way. One or both, of the drying zone 600 between the feeding zone 100 and the underpainting printing zone 200, and the drying zone 600 between the underpainting printing zone 200 and the pattern printing zone 300 can be used.

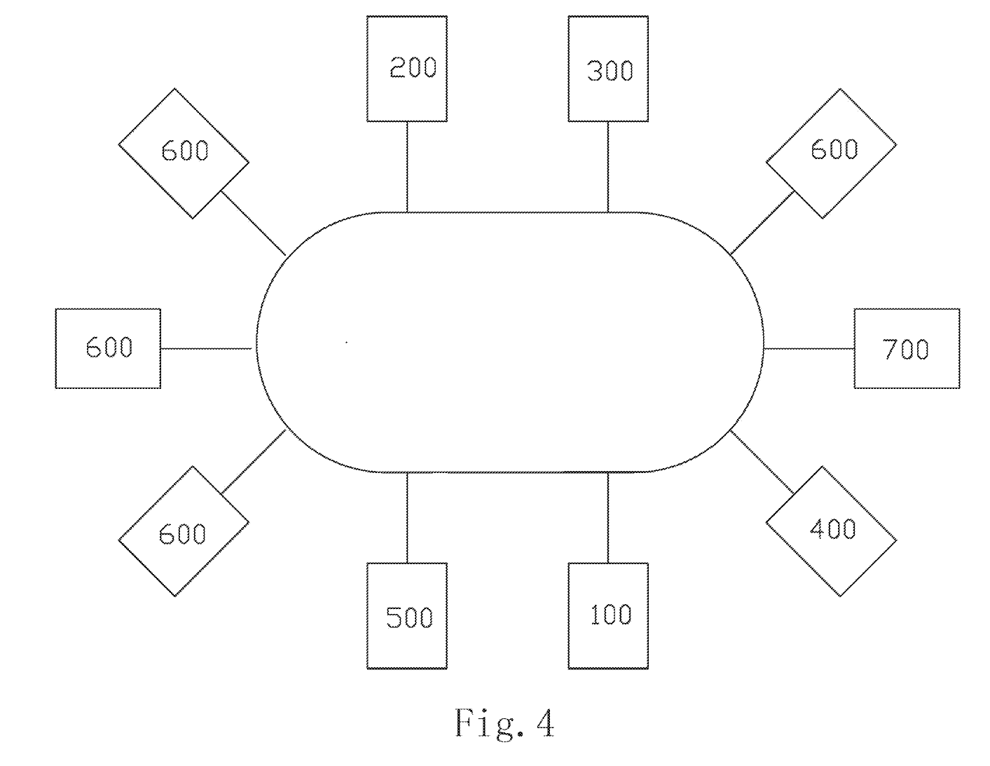

FIG. 4 shows a three-dimensional schematic diagram of the fourth embodiment of the present disclosure. As shown in the drawing, the difference between the fourth embodiment and the second embodiment lies in that, a glue spraying zone 700 is further arranged between the pattern printing zone 300 and the unloading zone 400. Further, the drying zone 600 can be further arranged between the glue spraying zone 700 and the pattern printing zone 300.

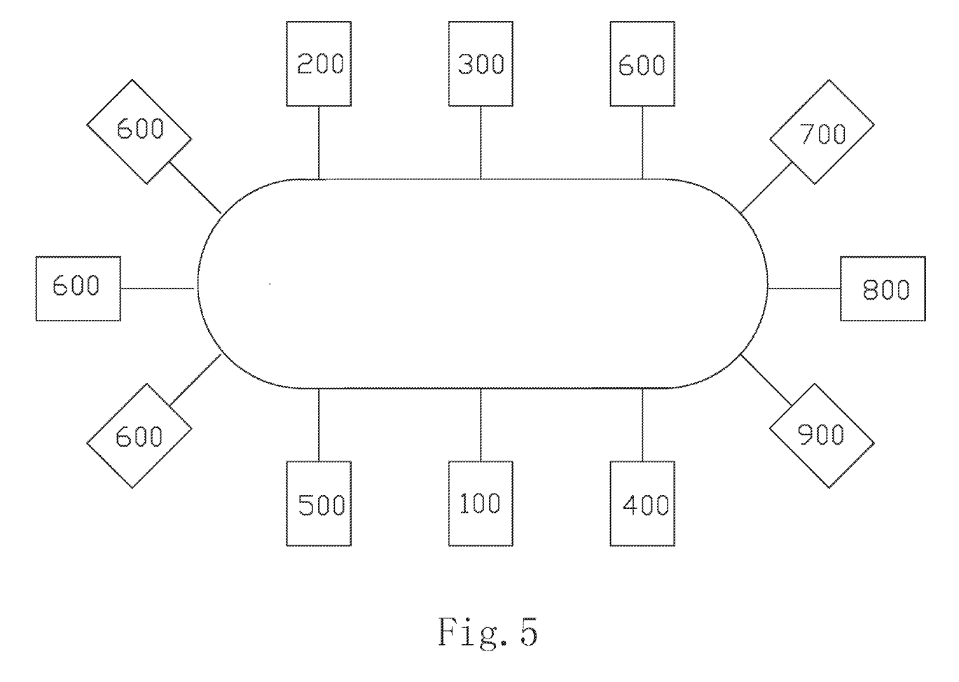

FIG. 5 shows a three-dimensional schematic diagram of the fifth embodiment of the present disclosure. As shown in The drawing, the difference between the fifth embodiment and the fourth embodiment lies in that, a flocking zone 800 and a gold blocking zone 900 are further arranged between the glue spraying zone 700 and the unloading zone 400, for adding flocking and gold blocking accessories on the medium. The flocking zone 800 and the gold blocking zone 900 are increased and decreased according to requirements, one or both of the two can be used, and the sequence of the two is not limited when both of the two can be used.

In the above various embodiments, it is preferably ensured that the quantity of the platens is not less than that of the functional zones, so that the platen in the unloading zone 400 can access into the feeding zone 100 in time after the platen in the feeding zone 100 accesses into the next functional zone.

According to the present disclosure, various additional functional zones can be arranged in different positions of the rack according to different process, which will not be elaborated herein.

The present disclosure further discloses a printing method based on digital printing, comprising the following steps:

S10: The printing device mentioned above is prepared, the printing device at least comprises a feeding zone 100, an underpainting printing zone 200, a pattern printing zone 300 and an unloading zone 400.

S20: A medium to be printed is fixed on the platen in the feeding zone 100, and it can be fixed by a binding element.

S30: The platen is moved through the underpainting printing zone 200, the pattern printing zone 300 and the unloading zone 400 one by one, the underpainting and the pattern are printed by digital printing respectively, and at last, the unloading operation is implemented in the unloading zone 400.

In combination with various preferred embodiments of the above printing device, the printing method further comprises a plurality of preferred steps, including but not limited to: a step of spraying pre-treating fluid before the step of printing underpainting; a step of drying before the step of printing underpainting and after completing the step of spraying pre-treating fluid; a step of drying before the step of printing pattern and after completing the step of printing underpainting; a step of spraying glue before the step of unloading and after the step of printing pattern; a step of drying before the step of spraying glue and after completing the step of printing pattern; a step of flocking before the step of unloading and after completing the step of spraying glue; and a step of gold blocking before the step of unloading and after completing the step of spraying glue, etc.

The above is the specific description of the preferred embodiments of the disclosure, but the disclosure is not intended to limit the foregoing embodiments. Those skilled in the art can further make various equivalent transformations or replacements within the present disclosure, which shall all fall within the protection scope limited by the claims. Accordingly, the appended claims are intended to encompass all such modifications and changes as fall within the true spirit and scope of this invention.

What is claimed is:

1. A printing device based on digital printing, wherein the printing device comprises:
a rack, wherein the rack is sequentially provided with a plurality of functional zones, wherein the functional zones comprise:
a feeding zone,
an underpainting printing zone,
a pattern printing zone and
an unloading zone;
and
a platen, wherein the platen is used for placing a medium to be printed, and is transferred among the feeding zone, the underpainting printing zone, the pattern printing zone and the unloading zone to achieve a continuous print process.

2. The printing device based on digital printing according to claim 1, wherein the functional zones further comprise a pre-treating fluid spraying zone arranged between the feeding zone and the underpainting printing zone.

3. The printing device based on digital printing according to claim 2, wherein the functional zones further comprise a drying zone arranged between the pre-treating fluid spraying zone and the underpainting printing zone, and/or between the underpainting printing zone and the pattern printing zone.

4. The printing device based on digital printing according to claim 1, wherein the functional zones further comprise a glue spraying zone arranged between the pattern printing zone and the unloading zone.

5. The printing device based on digital printing according to claim 4, wherein the functional zones further comprise a flocking zone and/or a gold blocking zone arranged between the glue spraying zone and the unloading zone.

6. The printing device based on digital printing according to claim 4, wherein the functional zones further comprise a drying zone arranged between the pattern printing zone and the glue spraying zone.

7. The printing device based on digital printing according to claim 1, wherein the feeding zone, the underpainting printing zone, the pattern printing zone and the unloading zone are annularly distributed.

8. The printing device based on digital printing according to claim 1, wherein the quantity of the platen is not less than that of the functional zones, so that a platen in the unloading zone accesses into the feeding zone after a platen in the feeding zone accesses into a next functional zone.

9. A printing method based on digital printing, comprising the following steps of:
S10: preparing a printing device, the printing device comprising a rack and a platen, the rack being provided with a feeding zone, an underpainting printing zone, a pattern printing zone and an unloading zone;
S20: fixing a medium to be printed on the platen in the feeding zone;
S30: moving the platen to the underpainting printing zone, printing underpainting in the underpainting printing zone in a digital printing mode;
S40: moving the platen to the pattern printing zone after completing underpainting printing, and printing a pattern in the pattern printing zone by digital printing; and
S50: moving the platen to the unloading zone after completing pattern printing, and implementing unloading operation in the unloading zone.

10. The printing method based on digital printing according to claim 9, further comprising a step of spraying pre-treating fluid before the step of printing underpainting.

11. The printing method based on digital printing according to claim 10, further comprising a step of drying before the step of printing pattern and after completing the step of spraying the pre-treating fluid.

12. The printing method based on digital printing according to claim 9, further comprising a step of spraying glue before the step of unloading and after the step of printing pattern.

13. The printing method based on digital printing according to claim 12, further comprising one of or combination of a step of flocking, a step of gold blocking and a step of drying before the step of unloading and after completing the step of spraying glue.
